(19) United States
(12) Patent Application Publication
(10) Pub. No.: US 2026/0262214 A1
(43) Pub. Date: Sep. 3, 2026

(54) INTEGRATED CIRCUIT DEVICE AND METHOD OF MANUFACTURING THE SAME

(71) Applicant: Taiwan Semiconductor Manufacturing Company, Ltd., Hsinchu (TW)

(72) Inventors: Sheng-Chih Lai, Hsinchu County (TW); Kenichi Sano, Hsinchu (TW); Ken-Ichi Goto, Hsin-Chu (TW)

(21) Appl. No.: 19/068,423

(22) Filed: Mar. 3, 2025

(51) Int. Cl. H10B 12/00

(52) U.S. Cl. CPC H10B 12/315; H10B 12/00; H10B 12/05

(57) ABSTRACT

In some embodiments, the present disclosure relates to an IC device including an array of cells. A semiconductor channel overlays the back gate, isolated from a back gate by a first dielectric layer. A lower portion of a top gate overlays and is in contact with the back gate. The top gate is isolated from the semiconductor channel by a first sidewall spacer; an upper portion overlays the semiconductor channel, isolated by a second dielectric layer, and isolated laterally from adjoining structures by a second sidewall spacer. A cascading portion connects the upper portion and the lower portion and overlays the first sidewall spacer. A first electrode is on a first side of the upper portion and in contact with the semiconductor channel. A second electrode is on the opposite side of the upper portion and in contact with the semiconductor channel.

### BACKGROUND

Thin-film transistor (TFT) technology, as the name suggests, allows for the fabrication of thin-film transistors for a multitude of types of devices. As TFT technology has developed, it has evolved to encompass new materials and new processes and to provide additional solutions for integrated circuit (IC) fabrication. Notably, TFT technology has been adopted in diverse domains such as, for example, displays, memory arrays, transparent devices, flexible devices, and sensors.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1A illustrates a simplified top view of an example portion of an integrated circuit following the formation of a back gate in a dielectric, in accordance with some embodiments of the disclosure.

FIG. 1B illustrates a cross-sectional view of the portion along a cut line of FIG. 1A.

FIG. 1C illustrates a cross-sectional view of the portion along another cut line of FIG. 1A.

FIG. 2A illustrates a simplified top view of the portion of FIG. 1A after formation of a metal oxide semiconductor channel.

FIG. 2B illustrates a cross-sectional view of the portion along the cut line B-B′ of FIG. 2A.

FIG. 2C illustrates a cross-sectional view of the portion along the cut line C-C′ of FIG. 2A.

FIG. 3A illustrates a simplified top view of the portion of FIG. 2A after deposition of dielectric.

FIG. 3B illustrates a cross-sectional view of the portion along the cut line B-B′ of FIG. 3A.

FIG. 3C illustrates a cross-sectional view of the portion along the cut line C-C′ of FIG. 3A.

FIG. 4A illustrates a simplified top view of the portion of FIG. 3A after etching the dielectric layer.

FIG. 4B illustrates a cross-sectional view of the portion along the cut line B-B′ of FIG. 4A.

FIG. 4C illustrates a cross-sectional view of the portion along the cut line C-C′ of FIG. 4A.

FIG. 5A illustrates a simplified top view of the portion of FIG. 4A after the formation of a top gate.

FIG. 5B illustrates a cross-sectional view of the portion along the cut line B-B′ of FIG. 5A.

FIG. 5C illustrates a cross-sectional view of the portion along the cut line C-C′ of FIG. 5A.

FIG. 6A illustrates a simplified top view of the portion of FIG. 5A after the formation of a gate cap over the top gate.

FIG. 6B illustrates a cross-sectional view of the portion along the cut line B-B′ of FIG. 6A.

FIG. 6C illustrates a cross-sectional view of the portion along the cut line C-C′ of FIG. 6A.

FIG. 7A illustrates a simplified top view of the portion of FIG. 6A after deposition of dielectric material.

FIG. 7B illustrates a cross-sectional view of the portion along the cut line B-B′ of FIG. 7A.

FIG. 7C illustrates a cross-sectional view of the portion along the cut line C-C′ of FIG. 7A.

FIG. 8A illustrates a simplified top view of the portion of FIG. 7A after etching the dielectric material.

FIG. 8B illustrates a cross-sectional view of the portion along the cut line B-B′ of FIG. 8A.

FIG. 8C illustrates a cross-sectional view of the portion along the cut line C-C′ of FIG. 8A.

FIG. 9A illustrates a simplified top view of the portion 800 of FIG. 8A after deposition of a dielectric layer.

FIG. 9B illustrates a cross-sectional view of the portion along the cut line B-B′ of FIG. 9A.

FIG. 9C illustrates a cross-sectional view of the portion along the cut line C-C′ of FIG. 9A.

FIG. 10A illustrates a simplified top view of the portion of FIG. 9A after the formation of source/drain electrodes.

FIG. 10B illustrates a cross-sectional view of the portion along the cut line B-B′ of FIG. 10A.

FIG. 10C illustrates a cross-sectional view of the portion along the cut line C-C′ of FIG. 10A.

FIG. 11A illustrates a simplified top view of the portion of FIG. 10A after the deposition of a dielectric.

FIG. 11B illustrates a cross-sectional view of the portion along the cut line B-B′ of FIG. 11A.

FIG. 11C illustrates a cross-sectional view of the portion along the cut line C-C′ of FIG. 11A.

FIG. 12A illustrates a simplified top view of the portion of FIG. 11A after the formation of metal plugs.

FIG. 12B illustrates a cross-sectional view of the portion along the cut line B-B′ of FIG. 12A.

FIG. 12C illustrates a cross-sectional view of the portion along the cut line C-C′ of FIG. 12A.

FIG. 13A illustrates a simplified top view of the portion of FIG. 12A after the deposition of a dielectric layer and the formation of metallization lines.

FIG. 13B illustrates a cross-sectional view of the portion along the cut line B-B′ of FIG. 13A.

FIG. 13C illustrates a cross-sectional view of the portion along the cut line C-C′ of FIG. 13A.

FIG. 13D illustrates a cross-sectional view of the portion along the cut line D-D′ of FIG. 13A.

FIG. 13E illustrates another simplified top view of the portion of FIG. 13A, but showing a rotated cut line.

FIG. 13F illustrates a rotated cross-sectional view of the portion along the rotated cut line E-F-G of FIG. 13E.

FIG. 14 illustrates a simplified top view of an example array of FETs, in accordance with some embodiments of the disclosure.

FIG. 15A illustrates a simplified top view of the portion of FIG. 13A following the formation of capacitors to form 1T1C memory cells.

FIG. 15B illustrates a cross-sectional view of the portion along the cut line B-B′ of FIG. 15A.

FIG. 15C illustrates a cross-sectional view of the portion along the cut line C-C′ of FIG. 15A.

FIG. 15D illustrates a cross-sectional view of the portion along the cut line D-D′ of FIG. 15A.

FIG. 16A illustrates a simplified top view of a portion corresponding to a second transistor formed over the transistors of, for example, FIG. 10C, to form 2T0C memory cells.

FIG. 16B illustrates a cross-sectional view of a portion, including a first transistor and second transistor along the cut line B-B′ of FIG. 16A.

FIG. 16C illustrates a cross-sectional view of the portion along the cut line C-C′ of FIG. 16A.

FIG. 17 is a flowchart illustrating an example method of forming an IC device in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Relatively recent developments in TFT technology have included the adoption of metal oxide semiconductor materials, also referred to as oxide semiconductors. Notably, oxide semiconductors may be better suited for back-end-of-line (BEOL) processes than traditional semiconductors since, for example, they are more compatible with the lower thermal budgets of BEOL processes. This allows, for example, the fabrication of stacked IC devices that include both front-end-of-line (FEOL) transistor devices and BEOL transistor devices. Accordingly, TFTs may be used, for example, to form random access memory (RAM) cells over processor logic, which allows for the integration of memory and processing in devices, which is sometimes referred to as compute-in-memory, in-memory computing, logic-in-memory, logic-memory integrated, monolithic devices, or other similar terms. This integration allows these devices to overcome some of the data transfer bottlenecks faced by traditional (e.g., von-Neumann) architectures. The memory cells may be, for example, dynamic RAM (DRAM) or static RAM (SRAM). In some implementations, structures formed at or above the third metallization layer over the device substrate are considered BEOL structures.

TFT DRAM cells may be in the form of, for example, two transistors and zero capacitors (2T0C) or one transistor and one capacitor (1T1C). The memory state of the cell is stored by capacitive elements of the cell, whether an explicit capacitor as in the 1T1C memory cell or inherent (sometimes also referred to as parasitic) capacitance as in the 2T0C memory cell. Due to the leakage of stored charge over time, DRAM cells regularly refresh themselves.

TFT memory cells may be fabricated so as to have a single gate per transistor. Notably, however, the performance of such memory cells may be limited, as indicated by performance metrics such as, for example, a high subthreshold slope, a large off-state current (I_{OFF}), a low on-state current ((I_{ON}), and low carrier mobility. The on-state current and off-state current metrics are sometimes combined into a single ratio metric corresponding to the ratio of I_{ON}/I_{OFF}. The above-described factors, as indicated by the above-described metrics, make it more difficult to reduce transistor power use and to improve operating (e.g., state transition) speed.

The subthreshold slope, also referred to as the subthreshold swing, provides a measure of the efficiency of a transistor's switch from the off state to the on state. It is typically measured as the gate voltage (V_{GS}) required to change the drain current (I_{D}) by one order of magnitude (e.g., by a multiplicative factor of ten), generally expressed as millivolts per decade (mV/dec). The relationship between the gate voltage and drain current of a transistor is commonly illustrated as a semi-log transfer curve that plots the drain current I_{D} on a logarithmic scale against the gate voltage V_{GS} on a linear scale, in which the subthreshold swing may be measured as the inverse slope of the curve. A lower subthreshold swing value is generally considered better.

The off-state current (I_{OFF}) of a transistor is the drain-source current when the gate voltage is below its threshold and generally corresponds to the transistor's leakage current. A lower off-state current indicates a lower leakage current and is generally considered better. The on-state current (I_{ON}) of a transistor is the drain-source current when the transistor is in its on state and the gate voltage is above its threshold. A higher on-state current allows for faster switching and is generally considered better. In view of the above, a higher I_{ON}/I_{OFF} ratio and is generally considered better.

Carrier mobility (μ) of a transistor measure the responsiveness of its charge carriers (e.g., electrons or holes) to an applied electric field and is typically measured in units of cm²/V·s. A particular transistor may be characterized by its field-effect mobility (μ_{FE}), which takes into account its particular features, such as channel geometry and transfer curve. A higher carrier mobility corresponds to a higher on-state current and faster switching and is generally considered better.

Using dual-gate TFTs provides improved operating characteristics such as, for example, a lower subthreshold swing and a higher on-state current (I_{ON}). For example, using a dual-gate OS TFT may reduce the subthreshold swing to about 73 mV/dec from about 105 mV/dec for a similar single-gate OS TFT. Similarly, a dual-gate OS TFT may support about double the on-state current compared to a similar single-gate OS TFT. Importantly, however, a dual-gate TFT structure typically requires several additional fabrication steps and requires significantly larger area per transistor as compared to a single-gate TFT structure, which significantly raises their cost. Beneficially, embodiments of this disclosure include structures and methods that permit the fabrication of dual-gate TFT structures requiring fewer fabrication steps and provide dual-gate TFT structures using less area than typical dual-gate TFT structures. Some embodiments use merely one additional mask and substantially the same area as compared to a corresponding single-gate TFT. These embodiments permit the fabrication of IC devices having greater densities of better-performing TFTs at minimal additional expense, thereby providing a greater performance for price ratio for these IC devices. This technology may be used, for example, for driver transistors of Magnetic RAM (MRAM), Phase Change RAM (PCRAM), and Resistive RAM (ReRAM).

In some embodiments of the disclosure, an integrated circuit (IC) device includes an array of memory cells, each cell including a dual-gate TFT device that has a back gate, a top gate, an oxide semiconductor channel between the back gate and the top gate, a source electrode, and a drain electrode, characterized by the following. The semiconductor channel overlays the back gate, isolated from the back gate by a first dielectric layer. The top gate includes an upper portion, a lower portion, and a cascading portion. The lower portion overlays and is in contact with the back gate. The top gate is isolated from the semiconductor channel by a first sidewall spacer. The upper portion overlays the semiconductor channel, is isolated from the semiconductor channel by a second dielectric layer, and is isolated laterally from adjoining structures by a second sidewall spacer. The cascading portion connects the upper portion and the lower portion and overlays the first sidewall spacer. The source electrode is on a first side of the upper portion of the top gate and in contact with the semiconductor channel. The drain electrode is on the opposite side of the upper portion of the top gate and in contact with the semiconductor channel.

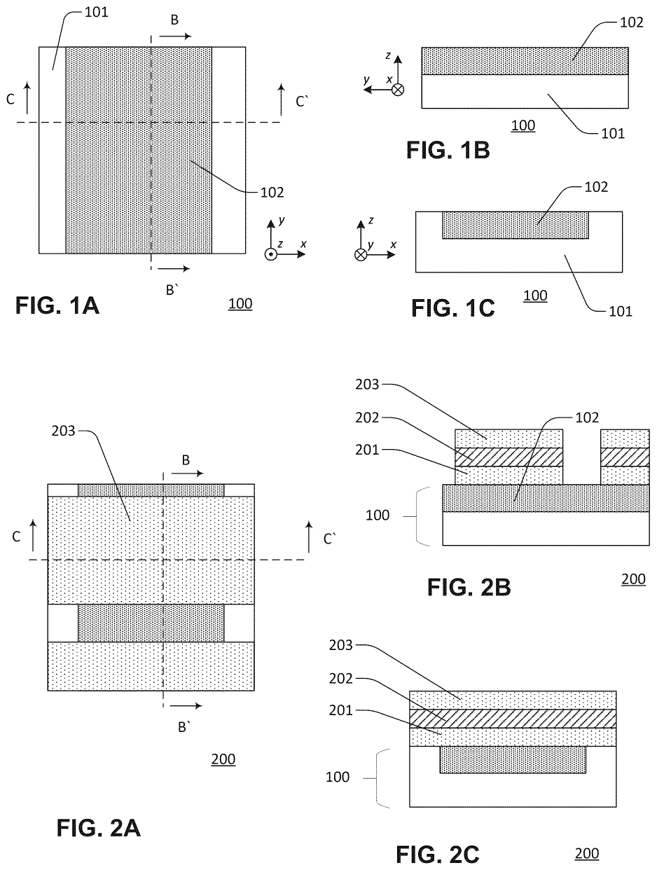

FIGS. 1-13 show simplified views of various example stages of manufacture of portions of an example integrated circuit (IC) devices in accordance with some embodiments of the disclosure. These portions include, for example, dual-gate TFT devices. Although these figures are described as a series of acts, it will be appreciated that these acts are not limiting in that the order of the acts can be altered in other embodiments, and the methods disclosed are also applicable to other structures. In some embodiments, some acts that are illustrated and/or described may be omitted in whole or in part. In some embodiment, additional acts that are not described herein may also be performed as part of the manufacturing process.

FIG. 1A illustrates a simplified top view of an example portion 100 of an integrated circuit following the formation of a back gate 102 in a dielectric 101. FIG. 1B illustrates a cross-sectional view of the portion 100 along the cut line B-B′ of FIG. 1A. FIG. 1C illustrates a cross-sectional view of the portion 100 along the cut line C-C′ of FIG. 1A. Illustrative coordinate axes (x, y, z) are provided along with these figures to assist with visual orientation and understanding of the features. It should be noted that the features illustrate may extend beyond the segments shown. For example, the back gate 102 may extend out along the y dimension, while the dielectric 101 may extend out along both the x and y dimensions. The back gate 102 may be considered to form a line or ribbon oriented along the y axis.

The dielectric 101 may be an interlayer dielectric (ILD) comprising, for example, low-k dielectrics (e.g., a dielectric material with a dielectric constant less than about 3.9), oxides (e.g., silicon dioxide (SiO₂)), nitrides (e.g., silicon nitride (Si₃N₄) (sometimes abbreviated as SiN), carbides (e.g., silicon carbide), oxy-nitrides (e.g., silicon oxy-nitride), oxy-carbides (e.g., silicon oxy-carbide), undoped silicate glass (USG), doped silicon dioxide (e.g., carbon doped silicon dioxide), borosilicate glass (BSG), phosphoric silicate glass (PSG), borophosphosilicate glass (BPSG), fluorinated silicate glass (FSG), a spin-on glass (SOG), or the like. The back gate 102 may be a conductor comprising, for example, titanium (Ti), titanium nitride (TiN), tungsten (W), tantalum nitride (TaN), copper (Cu), or any other suitable conductive material.

The materials may be deposited using, for example, atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, spin-on techniques, other suitable processes, and/or combinations thereof. The back gate 102 may be formed using a damascene process. The dielectric 101 may be patterned using a photolithographically developed photoresist, then etched using, for example, a dry etchant using a fluorine-containing gas (e.g., xenon fluoride (XeF₆), sulfur fluoride (SF₆), carbon fluoride (CF₄), or other suitable gas. After deposition of the metal for the back gate, the device may be planarized using, for example, a chemical mechanical planarization (CMP) process. Similar processes may be used for similar fabrication steps described below.

FIG. 2A illustrates a simplified top view of a portion 200, corresponding to the portion 100 of FIG. 1A after formation of metal oxide semiconductor channel 202, sandwiched between high-k dielectric layers 201 and 203, overlaying segments of the back gate 102 and the dielectric 101 of the portion 100. The oxide semiconductor (OS) channel 202 may be considered to form a line or ribbon perpendicular to the back gate line, e.g., along the x axis. FIG. 2B illustrates a cross-sectional view of the portion 200 along the cut line B-B′ of FIG. 2A. FIG. 2C illustrates a cross-sectional view of the portion 200 along the cut line C-C′ of FIG. 2A.

The channel sandwich of portion 200 may be formed, for example, by depositing all three layers—dielectric layers 201 and 203 and OS channel 202—and then etching all three together using, e.g., the photolithography and etching techniques described above. Alternatively, the channel sandwich of portion 200 may be formed one layer at time—e.g., depositing and etching dielectric layer 201, then depositing and etching OS channel layer 202, and then depositing and etching dielectric layer 203. Note that the same patterning mask (or masks) may be used for these processes.

The OS channel 202 may comprise an n-type OS such as, for example, indium gallium zinc oxide (InGaZnO, sometimes also abbreviated as IGZO), indium tungsten oxide (InWO), indium oxide (InO), or any suitable n-type metal oxide semiconductor. Alternatively, the OS channel 202 may comprise a p-type OS such as, for example, tin oxide (SnO), nickel oxide (NiO), copper oxide (Cu₂O), or any suitable p-type metal oxide semiconductor. The high-k dielectric layers 201 and 203 may comprise, for example, hafnium oxide (HfO₂), zirconium oxide (ZrO₂), aluminum oxide (Al₂O₃), magnesium oxide (MgO), hafnium silicon oxide (HfSiO), hafnium silicon oxynitride (HfSiON), hafnium tantalum oxide (HfTaO), hafnium titanium oxide (HfTiO), hafnium titanium tantalum oxide (HfTiTaO), hafnium aluminum oxynitride (HfAlON), hafnium zirconium oxide (HfZrO), other suitable high-k dielectric materials, or combinations thereof.

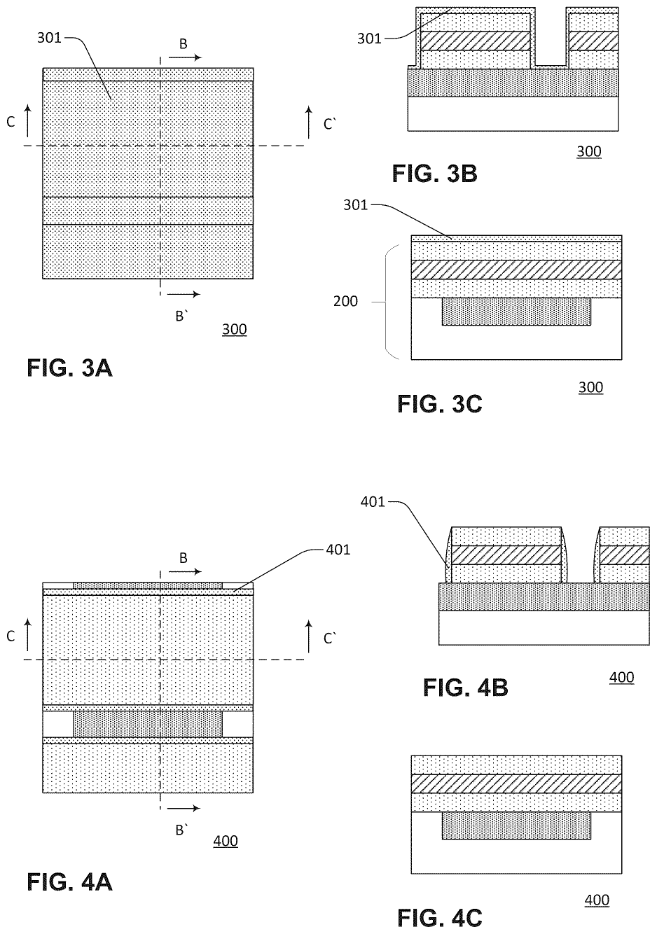

FIG. 3A illustrates a simplified top view of a portion 300, corresponding to the portion 200 of FIG. 2A after deposition of dielectric 301 for the subsequent formation of a first set of sidewall spacers. FIG. 3B illustrates a cross-sectional view of the portion 300 along the cut line B-B′ of FIG. 3A. FIG. 3C illustrates a cross-sectional view of the portion 200 along the cut line C-C′ of FIG. 3A. The dielectric 301 may be, for example, silicon nitride, silicon dioxide, silicon carbon nitride (SiCN), or any other suitable low-k dielectric, and may be deposited by any suitable deposition method as, for example, described above.

FIG. 4A illustrates a simplified top view of a portion 400, corresponding to the portion 300 of FIG. 3A after etching the dielectric layer 301 to form a first set of sidewall spacers 401. FIG. 4B illustrates a cross-sectional view of the portion 400 along the cut line B-B′ of FIG. 4A. FIG. 4C illustrates a cross-sectional view of the portion 400 along the cut line C-C′ of FIG. 4A. The dielectric 301 may be etched using anisotropic etching such as, for example, reactive ion etching (RIE), to remove horizontal sections of the dielectric 301 and leave behind the sidewall spacers 401.

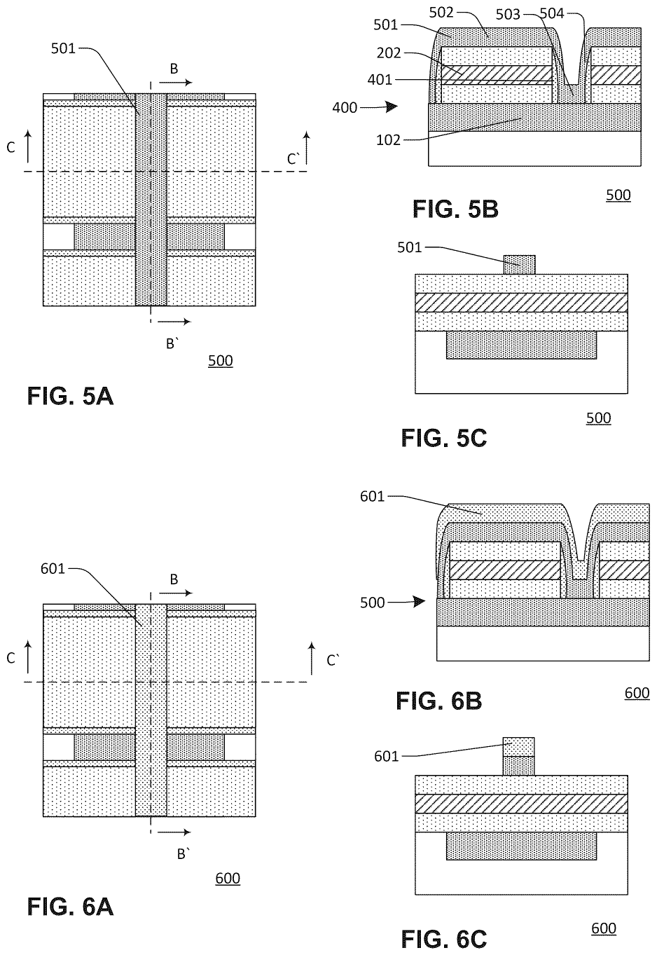

FIG. 5A illustrates a simplified top view of a portion 500, corresponding to the portion 400 of FIG. 4A after the formation of top gate 501. FIG. 5B illustrates a cross-sectional view of the portion 500 along the cut line B-B′ of FIG. 5A. FIG. 5C illustrates a cross-sectional view of the portion 500 along the cut line C-C′ of FIG. 5A.

FIG. 5C illustrates the ribbon-like characteristic of the top gate 501 as it follows the underlying contours, forming an upper portion 502 overlying the sandwiched OS channel 202, a lower portion 503 in contact with the back gate 102, and a cascading portion 504 connecting the upper portion 502 and the lower portion 503 and overlaying the sidewall spacers 401. The top gate 501 may comprise a conductive material such as any of the materials described above for the back gate 102. The top gate 501 may be formed by, for example, a deposition process and an etching process such as any corresponding process described above. Together, the bottom gate 102 and the top gate 501 form a dual gate to control the electrical properties of the OS channel disposed between them, which provides the various benefits described above.

FIG. 6A illustrates a simplified top view of a portion 600, corresponding to the portion 500 of FIG. 5A after the formation of a gate cap 601 over the top gate 501. FIG. 6B illustrates a cross-sectional view of the portion 600 along the cut line B-B′ of FIG. 6A. FIG. 6C illustrates a cross-sectional view of the portion 600 along the cut line C-C′ of FIG. 6A.

The gate cap 601 function to protect and insulate the top gate 501, similar to a passivation structure and helping prevent current leakage. The gate cap 601 may comprise a dielectric such as, for example, silicon nitride, silicon dioxide, silicon carbon nitride (SiCN), or any other similar suitable dielectric. The gate cap 601 may be formed by a deposition process and an etching process such as any corresponding process described above. It should be noted that in some embodiments, the formation of the top gate 501 and the gate cap 601 may be combined such that the dielectric for the gate cap 601 is deposited over the un-etched conductor for the top gate 501 and then both the top gate 501 and the gate cap 601 are etched together in a single etching step. Note that in some embodiments, the formation of a gate cap may be skipped.

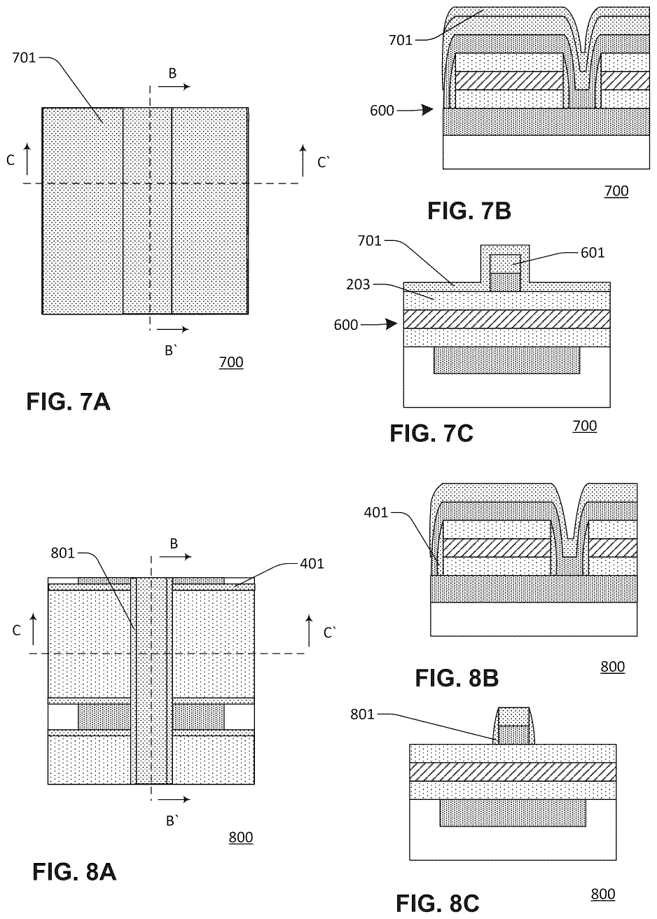

FIG. 7A illustrates a simplified top view of a portion 700, corresponding to the portion 600 of FIG. 6A after deposition of dielectric material 701 for the subsequent formation of the second set of sidewall spacers. FIG. 7B illustrates a cross-sectional view of the portion 700 along the cut line B-B′ of FIG. 7A. FIG. 7C illustrates a cross-sectional view of the portion 700 along the cut line C-C′ of FIG. 7A. The dielectric 701 may be, for example, silicon nitride, silicon dioxide, silicon carbon nitride (SiCN), or any other suitable low-k dielectric, and may be deposited by any suitable deposition method as, for example, described above.

FIG. 8A illustrates a simplified top view of a portion 800, corresponding to the portion 700 of FIG. 7A after etching the dielectric material 701 to form a second set of sidewall spacers 801. FIG. 8B illustrates a cross-sectional view of the portion 800 along the cut line B-B′ of FIG. 8A. FIG. 8C illustrates a cross-sectional view of the portion 800 along the cut line C-C′ of FIG. 8A. The dielectric 701 may be etched using anisotropic etching such as, for example, RIE, to remove horizontal sections of the dielectric 701 and leave behind the second set of sidewall spacers 801.

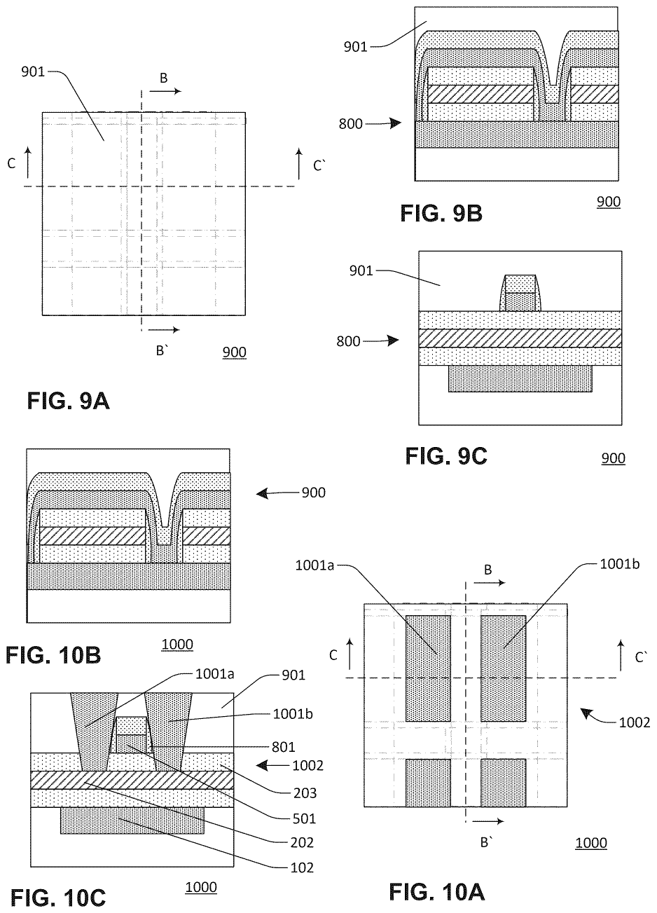

FIG. 9A illustrates a simplified top view of a portion 900, corresponding to the portion 800 of FIG. 8A after deposition of dielectric layer 901. FIG. 9B illustrates a cross-sectional view of the portion 900 along the cut line B-B′ of FIG. 9A. FIG. 9C illustrates a cross-sectional view of the portion 900 along the cut line C-C′ of FIG. 9A. The dielectric 901 may be an interlayer dielectric (ILD) comprising, for example, a low-k dielectric as described above in reference to dielectric 101 of FIG. 1A. The dielectric 901 may be deposited as described above in reference to dielectric 101.

FIG. 10A illustrates a simplified top view of a portion 1000, corresponding to the portion 900 of FIG. 9A after the formation of source/drain electrodes 1001. FIG. 10B illustrates a cross-sectional view of the portion 1000 along the cut line B-B′ of FIG. 10A. FIG. 10C illustrates a cross-sectional view of the portion 1000 along the cut line C-C′ of FIG. 10A.

The electrodes 1001 go through the dielectric 203 and contact the OS channel 202. The electrode 1001a is on a first side of the top gate 501 and the electrode 1001b is on the opposite side of the top gate 501. Together, the electrodes 1001a and 1001b, the gates 501 and 102, and OS channel 202 form a field-effect transistor (FET) 1002. The source terminal of the FET 1002 may be either electrode 1001a or 1001b, depending on how the encompassing circuit is configured, where the other electrode then functions as the drain terminal.

The electrodes 1001 may comprise conductive material such as, for example, titanium, tungsten, copper, palladium, nickel, gold, platinum, titanium nitride (TiN), tantalum nitride (TaN), or any other suitable conductive material. The electrodes 1001 may be formed using an etch, fill, and planarize process as, for example, described above. The second set of sidewall spacers 801, which laterally adjoin the electrodes 1001, may be used to self-align the electrodes 1001, which may reduce the number of photolithographic masks needed to form them.

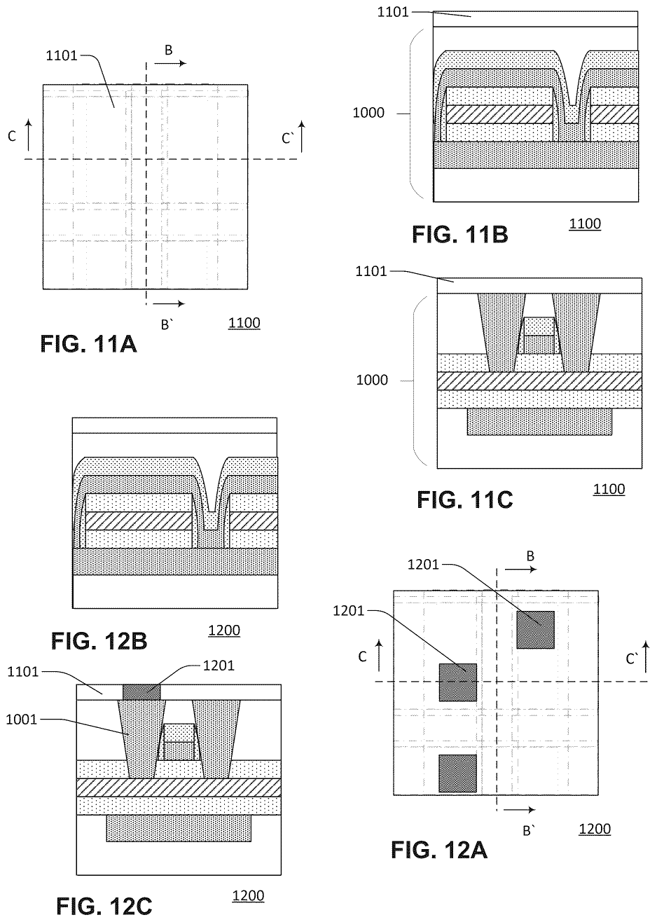

FIG. 11A illustrates a simplified top view of a portion 1100, corresponding to the portion 1000 of FIG. 10A after the deposition of a dielectric 1101. FIG. 11B illustrates a cross-sectional view of the portion 1100 along the cut line B-B′ of FIG. 11A. FIG. 11C illustrates a cross-sectional view of the portion 1100 along the cut line C-C′ of FIG. 11A. The dielectric 1101 may be an ILD such as, for example, silicon nitride, silicon dioxide, silicon carbon nitride (SiCN), or any other suitable low-k dielectric, and may be deposited by any suitable deposition method as, for example, described above.

FIG. 12A illustrates a simplified top view of a portion 1200, corresponding to the portion 1100 of FIG. 11A after the formation of metal plugs 1201 in the dielectric 1101. FIG. 12B illustrates a cross-sectional view of the portion 1200 along the cut line B-B′ of FIG. 12A. FIG. 12C illustrates a cross-sectional view of the portion 1200 along the cut line C-C′ of FIG. 12A. The metal plugs 1201 comprise a conductive material such as any described above. The metal plugs 1201 may be formed using, for example, etch, fill, and planarize processes as described above. The metal plugs 1201 are used to connect an electrode 1001 to a corresponding subsequently formed metallization line (e.g., a word line or a bit line). Metal plugs 1201 may be considered a stub via.

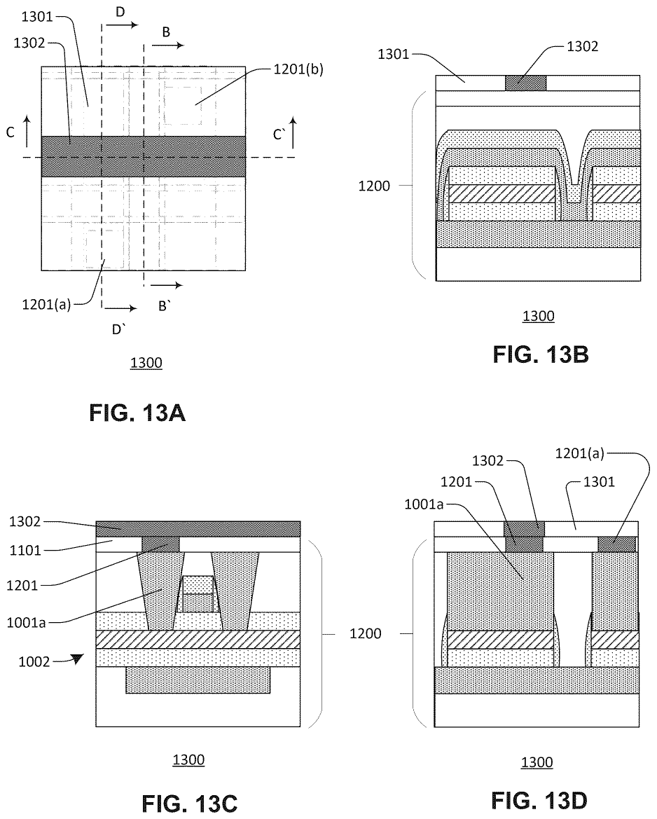

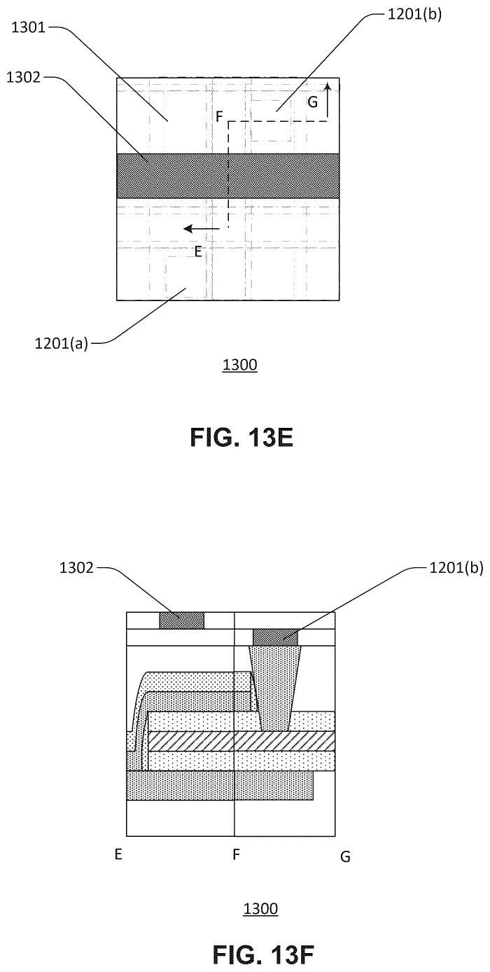

FIG. 13A illustrates a simplified top view of a portion 1300, corresponding to the portion 1200 of FIG. 12A after the deposition of a dielectric layer 1301 and the formation of metallization lines 1302 in the dielectric 1301. FIG. 13B illustrates a cross-sectional view of the portion 1300 along the cut line B-B′ of FIG. 13A. FIG. 13C illustrates a cross-sectional view of the portion 1300 along the cut line C-C′ of FIG. 13A. FIG. 13D illustrates a cross-sectional view of the portion 1300 along the cut line D-D′ of FIG. 13A. FIG. 13E illustrates another simplified top view of a portion 1300, corresponding to FIG. 13A, but showing a different cut line, namely the rotated cut line E-F-G. FIG. 13F illustrates a rotated cross-sectional view of the portion 1300 along the rotated cut line E-F-G of FIG. 13E.

The dielectric layer 1301 may be an ILD formed, for example, as described above in reference to earlier ILD layers. The metallization line 1302 illustrated may be, for example, a bit line for a memory array including the transistor of the portion 1300. The metallization line 1302 may comprise any conductor such as, for example, the conductive materials described above. The metallization line 1302 may be formed using any suitable process, such as, for example, the conductor forming processes described above. It should be noted that, in some implementations, the processes of FIGS. 11, 12, and 13 may be combined into a dual-damascene process, where the dielectric layers 1101 and 1301 are deposited in one step, followed by the etching of contact holes for the metal plugs 1201 and the etching of trenches for the metallization line 1302, then followed up by deposition of metal, or other conductor, into both the etched holes and tranches, followed by planarization. These conductive connections allow the dual-gate OS FET 1002 to connect to other components of an enclosing IC device, such as, for example, logic circuitry.

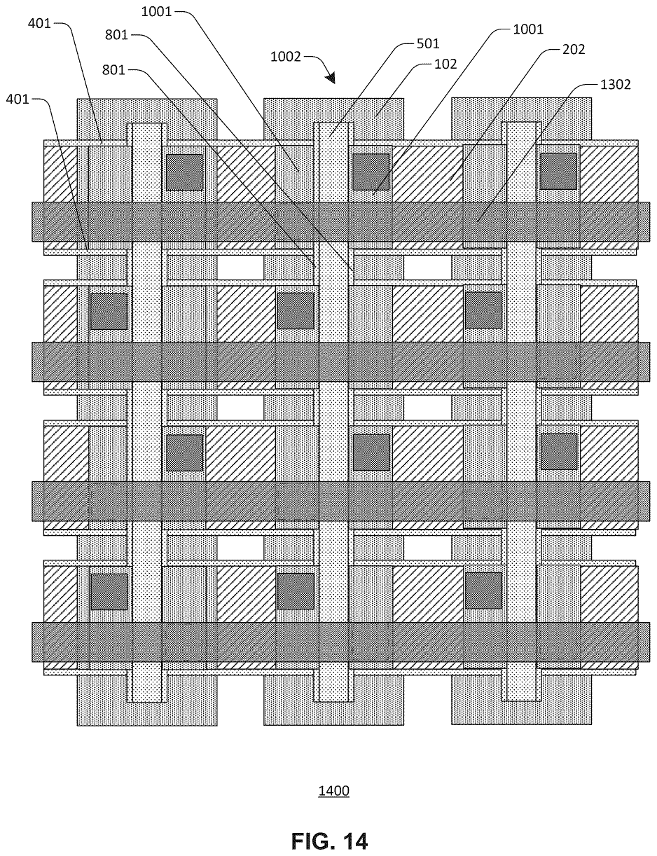

FIG. 14 illustrates a simplified top view of an example array 1400 of FETs, such as, for example, FET 1002, in accordance with embodiments of the disclosure. The back gates 102 form a plurality of parallel word lines. The channels 202 form a plurality of parallel semiconductor channel lines perpendicular to and intersecting these word lines. The sidewall spacers 401 laterally adjoin these semiconductor channel lines. The top gates 501 form top-gate ribbons corresponding to the above-described word lines. The sidewall spacers 801 laterally adjoin these top-gate ribbons. At each intersection of word lines (back gates 102) and semiconductor channel lines (channels 202), there are two source/drain electrodes 1001 on opposite sides of the corresponding top gate 501, each in contact with the channel 202. Arrays like array 1400 may be used, for example, to form memory arrays by, as described below, providing a corresponding capacitor or transistor to each transistor 1002 of the array.

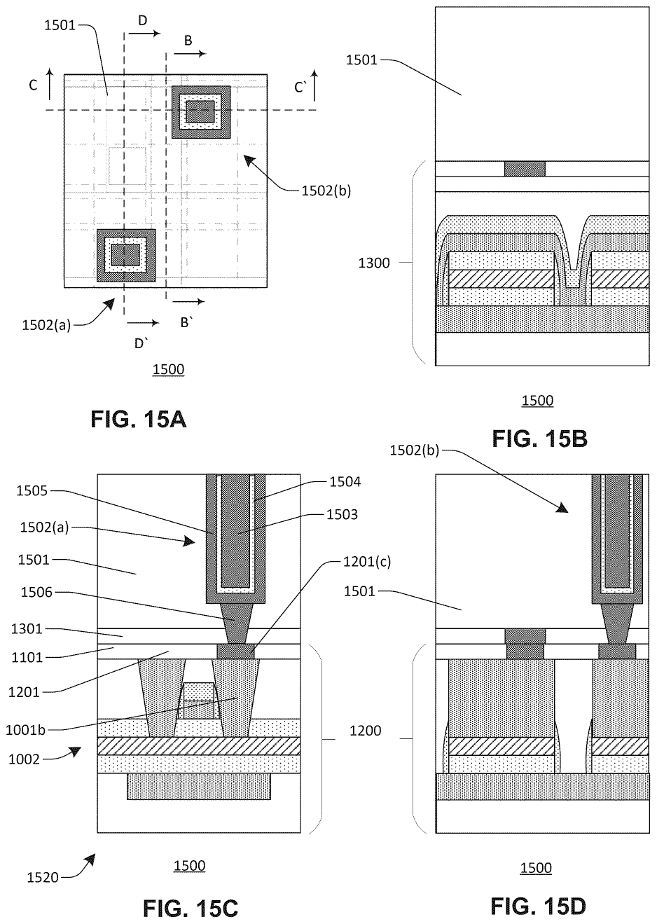

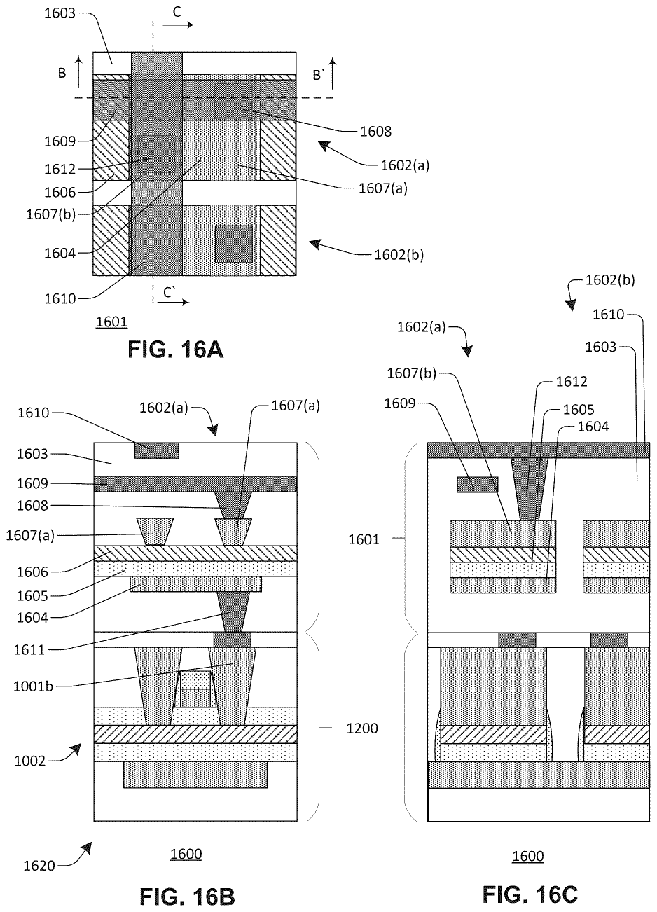

FIGS. 15-16 illustrate the use of the FET 1002, as shown in FIG. 13, as part of various example IC devices in accordance with embodiments of the disclosure. As described below, these example IC devices include 1T1C and 2T0C memory cells.

FIG. 15A illustrates a simplified top view of a portion 1500, corresponding to the portion 1300 of FIG. 13A following the formation of capacitors 1502 over the transistors 1002 to form 1T1C memory cells. FIG. 15B illustrates a cross-sectional view of the portion 1500 along the cut line B-B′ of FIG. 15A. FIG. 15C illustrates a cross-sectional view of the portion 1500 along the cut line C-C′ of FIG. 15A. FIG. 15D illustrates a cross-sectional view of the portion 1500 along the cut line D-D′ of FIG. 15A.

The capacitor 1502 is formed in a dielectric layer 1501 deposited over the dielectric layer 1301 of the portion 1300. The capacitor 1502 comprises an inner conductive element 1503, an outer conductive element 1505, and interposing high-k insulating dielectric element 1504. The conductive elements 1503 and 1505 may comprise, for example, any of the conductive materials noted above. Similarly, the insulating element 1504 may comprise, for example, any of the high-k dielectric materials noted above. In some implementations, the inner element 1503 may be substantially cylindrical or prismatic, with the dielectric 1504 and the outer element 1505, respectively, surrounding the inner element laterally and below, and substantially conforming in form to the inner element 1503.

The outer element 1505 of the capacitor 1502 conductively connects to an electrode 1001 of the corresponding transistor 1002 with a conductive via 1506. The inner element 1503 of the capacitor 1502 conductively connects to a common voltage (e.g., ground). The gate of the transistor 1002 is connected to the word line, while the drain electrode is connected to the bit line. Connected together, the FET 1002 and the corresponding capacitor 1502 form a 1T1C memory cell 1520.

FIG. 16A illustrates a simplified top view of a portion 1601, corresponding to a second transistor 1602 formed over the transistors 1002 of, for example, FIG. 10C, to form 2T0C memory cells. Note that, for improved clarity, the view of FIG. 16A does not illustrate elements of the underlying first transistor 1002. FIG. 16B illustrates a cross-sectional view of a portion 1600, including first transistor 1002 and second transistor 1602(a) along the cut line B-B′ of FIG. 16A. FIG. 16C illustrates a cross-sectional view of the portion 1600, including first transistor 1002 and second transistor 1602(a) along the cut line C-C′ of FIG. 16A.

The second transistors 1602 (e.g., 1602(a)) are formed in ILD layers 1603 deposited over the first transistor 1002. A second transistor comprises a back gate 1604 overlayed by a high-k dielectric 1605, which is, in turn, overlayed by a p-type oxide semiconductor channel 1606. The OS channel 1606 may comprise, for example, tin oxide (SnO), nickel oxide (NiO), copper oxide (Cu₂O), or any suitable p-type metal oxide semiconductor. Note that the materials for the other components of the second transistor may be any of the corresponding materials (e.g., conductors, dielectrics, etc.) described above. Drain/source electrodes 1607 (e.g., electrodes 1607(a) and 1607(b)) connect to the OS channel 1606 over the back gate 1604. The electrodes connect to metallization lines such as read word lines 1609 or read bit lines 1610 by vias such as via 1608 and via 1612. The back gate 1604 may connect to the first transistor using via 1611.

In one example implementation, electrode 1001b of the first transistor is connected to the back gate 1604 of the second transistor, which functions as the storage node for the corresponding memory cell. Electrode 1607(b) is connected to read bit line 1610 by via 1612, while electrode 1607(a) is connected to read word line 1609 by via 1608. Connected together thus, the first transistor 1002 and the corresponding second transistor 1602 form a 2T0C memory cell 1620.

It should be noted that in alternative embodiments, the second transistor may also be a dual-gate transistor. It should be noted, however, that since the second transistor is a read transistor, the performance gains of using a more expensive dual-gate are not as significant as having a dual-gate write transistor. It should also be noted that the second transistor may, alternatively, be an n-type transistor (in other words, having an n-type OS for the channel).

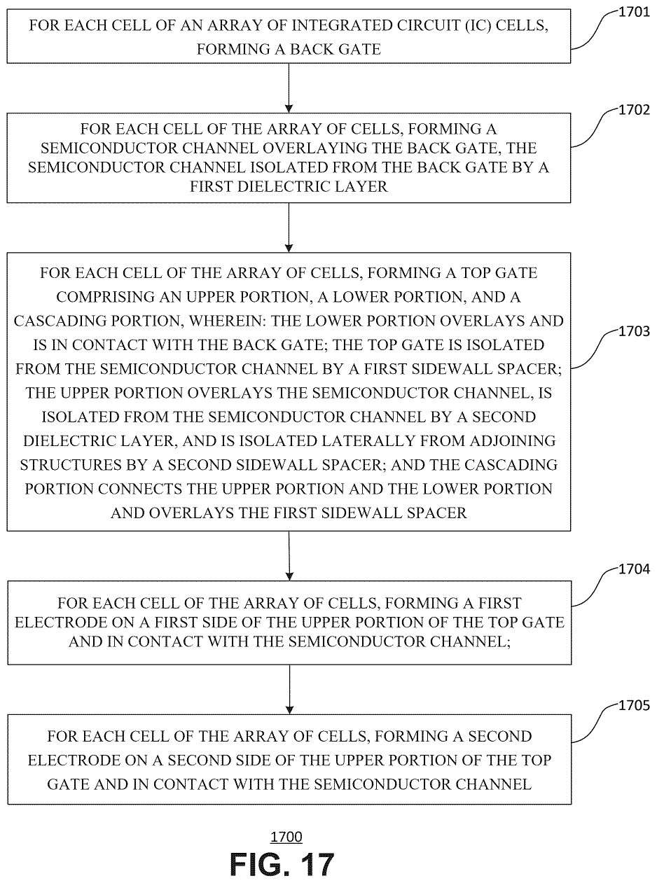

FIG. 17 is a flowchart illustrating an example method 1700 of forming an IC device in accordance with some embodiments of the disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included. Acts can correspond, for example, to the structures previously illustrated in FIGS. 1-13 in some embodiments.

At act 1701, for each cell of an array of integrated circuit (IC) cells, a back gate is formed. FIGS. 1A-1C illustrate views of some embodiments corresponding to act 1701.

At act 1702, for each cell of the array of cells, a semiconductor channel overlaying the back gate is formed, the semiconductor channel isolated from the back gate by a first dielectric layer. FIGS. 2A-2C illustrate views of some embodiments corresponding to act 1702.

At act 1703, for each cell of the array of cells, a top gate is formed comprising an upper portion, a lower portion, and a cascading portion, wherein: the lower portion overlays and is in contact with the back gate; the top gate is isolated from the semiconductor channel by a first sidewall spacer; the upper portion overlays the semiconductor channel, is isolated from the semiconductor channel by a second dielectric layer, and is isolated laterally from adjoining structures by a second sidewall spacer; and the cascading portion connects the upper portion and the lower portion and overlays the first sidewall spacer. FIGS. 5A-5C illustrate views of some embodiments corresponding to act 1703.

At act 1704, for each cell of the array of cells, a first electrode is formed on a first side of the upper portion of the top gate and in contact with the semiconductor channel. FIGS. 10A-10C illustrate views of some embodiments corresponding to act 1704.

At act 1705, for each cell of the array of cells, a second electrode is formed on a second side of the upper portion of the top gate and in contact with the semiconductor channel. FIGS. 10A-10C illustrate views of some embodiments corresponding to act 1705.

While embodiments of the disclosure have been described where TFTs are fabricated over a semiconductor substrate, it should be noted that, since TFTs may be fabricated over a variety of different types of substrates, in other embodiments, the TFTs are fabricated over alternative substrates such as, for example, glass or other insulator material. In general, TFTs in accordance with embodiments of the disclosure may be fabricated over any suitable substrate.

Accordingly, in some embodiments, the present disclosure relates to an integrated circuit (IC) device having an array of cells. Each cell of the array includes a back gate, a semiconductor channel, a top gate, a first electrode, and a second electrode. The semiconductor channel overlays the back gate, isolated from the back gate by a first dielectric layer. The top gate includes an upper portion, a lower portion, and a cascading portion. The lower portion overlays and is in contact with the back gate. The top gate is isolated from the semiconductor channel by a first sidewall spacer. The upper portion overlays the semiconductor channel, is isolated from the semiconductor channel by a second dielectric layer, and is isolated laterally from adjoining structures by a second sidewall spacer. The cascading portion connects the upper portion and the lower portion and overlays the first sidewall spacer. The first electrode is on a first side of the upper portion of the top gate and in contact with the semiconductor channel. The second electrode is on a second side of the upper portion of the top gate and in contact with the semiconductor channel.

In other embodiments, the present disclosure relates to a method including forming an array of integrated circuit (IC) cells. For each cell, the forming includes: forming a back gate, forming a semiconductor channel overlaying the back gate, forming a top gate, forming a first electrode, and forming a second electrode. The semiconductor channel is isolated from the back gate by a first dielectric layer. The top gate includes an upper portion, a lower portion, and a cascading portion. The lower portion overlays and is in contact with the back gate. The top gate is isolated from the semiconductor channel by a first sidewall spacer. The upper portion overlays the semiconductor channel, is isolated from the semiconductor channel by a second dielectric layer, and is isolated laterally from adjoining structures by a second sidewall spacer. The cascading portion connects the upper portion and the lower portion and overlays the first sidewall spacer. The first electrode is on a first side of the upper portion of the top gate and in contact with the semiconductor channel. The second electrode is on a second side of the upper portion of the top gate and in contact with the semiconductor channel.

In yet other embodiments, the present disclosure relates to a method including: forming a plurality of parallel word lines, forming a plurality of parallel semiconductor channel lines perpendicular to and intersecting the word lines, forming a first set of sidewall spacers laterally adjoining the semiconductor channel lines, forming a plurality of top-gate ribbons corresponding to the word lines, and forming a second set of sidewall spacers laterally adjoining the top-gate ribbons. The method further includes forming, at the intersections of the word lines and the semiconductor channel lines: a first electrode on a first side of the top gate and in contact with the semiconductor channel and a second electrode on a second side of the top gate and in contact with the semiconductor channel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising an array of cells, each cell of the array comprising:
a back gate;
a semiconductor channel overlaying the back gate, isolated from the back gate by a first dielectric layer;
a top gate comprising an upper portion, a lower portion, and a cascading portion, wherein:
the lower portion overlays and is in contact with the back gate;
the top gate is isolated from the semiconductor channel by a first sidewall spacer;
the upper portion overlays the semiconductor channel, is isolated from the semiconductor channel by a second dielectric layer, and is isolated laterally from adjoining structures by a second sidewall spacer; and
the cascading portion connects the upper portion and the lower portion and overlays the first sidewall spacer;
a first electrode on a first side of the upper portion of the top gate and in contact with the semiconductor channel; and
a second electrode on a second side of the upper portion of the top gate and in contact with the semiconductor channel.

2. The device of claim 1, wherein:
the back gate and the top gate form a gate terminal of a first field-effect transistor (FET);
the first electrode forms a source terminal of the first FET; and
the second electrode forms a drain terminal of the first FET.

3. The device of claim 2, wherein each cell of the array:
further comprises a capacitor connected to the source terminal of the first FET; and
forms a one-transistor one-capacitor (1T1C) memory cell.

4. The device of claim 2, wherein each cell of the array:
further comprises a second FET comprising a source terminal, a drain terminal, a semiconductor channel connecting the source and drain terminals, and a gate terminal, whose gate terminal is connected to the source terminal of the first FET; and
forms a two-transistor zero-capacitor (2T0C) memory cell, where the gate terminal of the second FET functions as a storage node for the memory cell.

5. The device of claim 4, wherein:
the semiconductor channel of the first FET comprises an n-type metal oxide semiconductor; and
the semiconductor channel of the second FET comprises a p-type metal oxide semiconductor.

6. The device of claim 1, wherein:
the semiconductor channel comprises an n-type metal oxide semiconductor;
the first electrode comprises a conductor; and
the second electrode comprises a conductor.

7. The device of claim 1, wherein:
the array of cells is formed in a back-end-of-line (BEOL) layer of the device;
the device further comprises logic circuitry in a front-end-of-line layer (FEOL) of the device; and
the array of cells is configured to function as a memory array for the logic circuitry.

8. The device of claim 1, wherein:
the array of cells is arranged as a grid;
one or more adjoining cells along a first axis share the semiconductor channel; and
one or more adjoining cells along a second axis, perpendicular to the first axis, share the top gate and the back gate.

9. A method comprising:
forming an array of integrated circuit (IC) cells, wherein, for each cell, the forming comprises:
forming a back gate;
forming a semiconductor channel overlaying the back gate, the semiconductor channel isolated from the back gate by a first dielectric layer;
forming a top gate comprising an upper portion, a lower portion, and a cascading portion, wherein:
the lower portion overlays and is in contact with the back gate;
the top gate is isolated from the semiconductor channel by a first sidewall spacer;
the upper portion overlays the semiconductor channel, is isolated from the semiconductor channel by a second dielectric layer, and is isolated laterally from adjoining structures by a second sidewall spacer; and
the cascading portion connects the upper portion and the lower portion and overlays the first sidewall spacer;
forming a first electrode on a first side of the upper portion of the top gate and in contact with the semiconductor channel; and
forming a second electrode on a second side of the upper portion of the top gate and in contact with the semiconductor channel.

10. The method of claim 9, wherein:
the back gate and the top gate form a gate terminal of a first field-effect transistor (FET);
the first electrode forms a source terminal of the first FET; and
the second electrode forms a drain terminal of the first FET.

11. The method of claim 10, further comprising, for each cell of the array, further forming a capacitor connected to the source terminal of the first FET to form a one-transistor one-capacitor (1T1C) memory cell.

12. The method of claim 10, further comprising, for each cell of the array, forming a second FET comprising a source terminal, a drain terminal, a semiconductor channel connecting the source and drain terminals, and a gate terminal, whose gate terminal is connected to the source terminal of the first FET, so as to form a two-transistor zero-capacitor (2T0C) memory cell, where the gate terminal of the second FET functions as a storage node for the memory cell.

13. The method of claim 12, wherein:
the semiconductor channel of the first FET comprises an n-type metal oxide semiconductor; and
the semiconductor channel of the second FET comprises a p-type metal oxide semiconductor.

14. The method of claim 13, wherein:
the semiconductor channel of the first FET comprises an n-type metal oxide semiconductor;
the first electrode comprises a conductor; and
the second electrode comprises a conductor.

15. The method of claim 9, comprising:
forming logic circuitry in a front-end-of-line (FEOL) layer;
forming the array of cells in a back-end-of-line (BEOL) layer; and
configuring the array of cells to function as a memory array for the logic circuitry.

16. The method of claim 9, comprising arranging the array of cells as a grid, wherein:
one or more adjoining cells along a first axis share the semiconductor channel; and
one or more adjoining cells along a second axis, perpendicular to the first axis, share the top gate and the back gate.

17. The method of claim 9, wherein the gates and channels are formed using atomic layer deposition.

18. The method of claim 9, wherein the first and second electrode are formed using the second sidewall spacer.

19. A method comprising:
forming a plurality of parallel word lines;
forming a plurality of parallel semiconductor channel lines perpendicular to and intersecting the word lines;
forming a first set of sidewall spacers laterally adjoining the semiconductor channel lines;
forming a plurality of top-gate ribbons corresponding to the word lines;
forming a second set of sidewall spacers laterally adjoining the top-gate ribbons;
forming, at the intersections of the word lines and the semiconductor channel lines:
a first electrode on a first side of the top gate and in contact with the semiconductor channel; and
a second electrode on a second side of the top gate and in contact with the semiconductor channel.

20. The method of claim 19, wherein the first and second electrodes are formed using the second set of sidewall spacers.
